(19) United States
(12) Patent Application Publication
(10) Pub. No.: US 2017/0342566 A1
(43) Pub. Date: Nov. 30, 2017

(54) WASHING SOLUTION FOR SURFACE OF ELECTROLESS TIN PLATING FILM, REPLENISHING SOLUTION FOR SAID WASHING SOLUTION, AND METHOD FOR FORMING TIN PLATING LAYER

(71) Applicant: MEC COMPANY LTD., Hyogo (JP)

(72) Inventors: Yuko SHIBANUMA, Hyogo (JP); Tatsuya GODA, Hyogo (JP); Jojiro NIGORO, Hyogo (JP); Tomoko ICHIHASHI, Hyogo (JP); Keisuke JOKO, Hyogo (JP); Takahiro YAMADA, Hyogo (JP); Tsuyoshi AMATANI, Hyogo (JP)

(73) Assignee: MEC COMPANY LTD., Hyogo (JP)

(21) Appl. No.: 15/537,963

(22) PCT Filed: Sep. 17, 2015
(86) PCT No.: PCT/JP2015/076490

§ 371 Date: Jun. 20, 2017

(30) Foreign Application Priority Data
Dec. 25, 2014 (JP) 2014-263252

(51) Int. Cl. C23C 18/16; H05K 3/18; H05K 3/26

(52) U.S. Cl. CPC C23C 18/1689; H05K 3/26; H05K 3/187; H05K 2203/072

(57) ABSTRACT

The invention relates to a washing solution for a tin plating film after electroless tin plating and before water washing. The invention also relates to a method for forming a tin plating film, the method includes a step of washing step using the washing solution. The washing solution according to the present invention is an acidic aqueous solution containing an acid, a complexing agent, a stabilizer and a chloride ion. The washing solution has a chloride ion concentration of 2 wt % or more, and a tin concentration of 0.5 wt % or less. The washing solution according to the present invention has good washing property for a tin plating film surface, and allows a tin plating film to easily maintain its properties. In addition the washing solution causes little influence on a tin plating film surface even when continuously used and is excellent in temporal stability.

### TECHNICAL FIELD

The invention relates to a washing solution for washing a tin plating film with a plating solution deposited on a surface thereof after electroless plating, and a replenishing solution for the washing solution. The invention also relates to a method for forming a tin plating layer, the method including a washing process using the washing solution.

### BACKGROUND ART

A common multilayer wiring board is produced in the following manner: an inner layer substrate having an electrically conductive layer composed of copper, a copper alloy or the like is laminated and pressed to other inner layer substrate, a copper foil or the like with a prepreg sandwiched therebetween. Electrically conductive layers are electrically connected through an open hole called a through-hole which is plated with copper on a hole wall. As a known method for improving adhesion between an electrically conductive layer and resin or solder of a prepreg etc., a fine irregularity shape is formed on a surface of an electrically conductive layer using a roughening agent (microetching agent), or a metal layer having high adhesion with resin (to-resin adhesive layer) is formed on a surface of an electrically conductive layer.

Particularly, in a high-frequency wiring board, an electrically conductive layer is required to have small surface roughness for reducing a transmission loss of electric signals. Thus, a method is widely employed in which a to-resin adhesive layer is formed on a surface of an electrically conductive layer to improve adhesion with resin or solder. As a known method for forming a to-resin adhesive layer on a surface of an electrically conductive layer, a tin layer (tin alloy layer) is formed by electroless plating (see, for example, Patent Document 1 and Patent Document 2). Generally, a substrate after formation of a tin film by electroless plating is dried after a plating solution deposited on a surface of the substrate is washed off by rinsing.

The electroless tin plating solution is a tin ion-containing acidic solution. When a tin film with an electroless tin plating solution deposited on a surface thereof is water rinsed, the pH environment of the film surface is rapidly changed from being acidic to being neutral (pH shock). In water rinsing of an electroless tin plating film, crystals of a tin salt such as tin hydroxide may be precipitated on a film surface as a surface environment is rapidly changed as described above. Particularly, when a plating solution is continuously used, or a throughput (washing area) in a rinsing bath increases, crystals tend to be markedly precipitated. Precipitation of crystals on a surface of a tin plating film leads to reduction of adhesion with resin, solder or the like, deterioration of reliability of a wiring board, and so on. When a substrate is conveyed by a roll conveyance method etc., and processes ranging from plating to water rinsing is continuously carried out (conveyorized process), there may be the problem that crystals deposited on a film surface are transferred to a substrate conveyance pathway (conveyance roll, bath wall surface and so on), leading to occurrence of process contamination. For preventing such a problem, it is necessary to frequently replace a plating solution in a plating bath and water in a rinsing bath, and therefore the advantage of continuous production by conveyorized process is reduced.

A method has been suggested in which washing with an acidic washing solution is performed after electroless tin plating and before water rinsing in order to prevent precipitation of crystals on a tin plating film surface during water rinsing. For example, Patent Document 3 suggests that after electroless tin plating and before water rinsing, washing is performed with an undegraded electroless tin plating solution (unused fresh solution).

### PRIOR ART DOCUMENTS

### Patent Documents

Patent Document 1: Japanese Patent Laid-open Publication No. 2005-23301

Patent Document 2: Japanese Patent Laid-open Publication No. 2010-111748

Patent Document 3: Japanese Patent Laid-open Publication No. 2007-169746

### SUMMARY OF THE INVENTION

### Problems to be Solved by the Invention

In washing after electroless tin plating, it is required to prevent precipitation of crystals on a surface of a plating film, and ensure that a substrate after washing has properties (surface shape, composition of plating film, adhesion with resin or solder, and so on) comparable to those in rising. Patent Document 3 is considered to suggest that washing (washing with an acidic solution such as a plating solution) after electroless tin plating is performed under the condition of a lower temperature and a shorter time as compared to the condition during formation of a tin film by electroless plating, whereby not only washing property is secured (precipitation of crystals is suppressed), but also properties of the plating film are maintained. However, when a plating solution as a washing solution is brought into contact with a tin plating film, tin ions in the washing solution cause re-plating (formation of a tin film), so that it may be difficult to maintain and control properties of the plating film.

Further, as a result of conducting studies, the inventors have found that when an acidic washing solution is repeatedly or continuously used, precipitation or sedimentation of crystals are generated in the washing solution even when crystals are not precipitated on a tin plating film surface, the precipitates are deposited on the plating film, leading to deterioration of properties. Particularly, in a conveyorized process, a treatment is performed while a solution is stirred in the processes of plating, washing with an acidic washing solution and water rinsing, and therefore precipitation or sedimentation of crystals in the washing solution causes a problem of secondary contamination such that the precipitates or sediments are deposited on the tin plating film.

In view of the situations described above, an object of the present invention is to provide a tin plating film washing solution which has good washing property for a tin plating film surface, allows a tin plating film to easily maintain its properties, and can be continuously used for a long period of time.

### Means for Solving the Problems

The inventors have conducted studies, and resultantly found that when a surface of an electroless tin plating film is washed using a washing solution that is substantially free of tin, precipitation of crystals in subsequent rinsing is suppressed, and properties of the tin plating film can be maintained. The inventors have also found that when the washing solution contains a specific amount of chloride ions, precipitation or sedimentation of crystals in the solution can be suppressed even when the washing solution is continuously used.

The present invention relates to a washing solution for washing an electroless tin plating film with a tin ion-containing acidic plating solution deposited on a surface thereof. The washing solution of the present invention is an acidic aqueous solution containing an acid, a complexing agent, a stabilizer and chloride ions. The chloride ion concentration in the solution is 2 wt % or more, and the tin concentration in the solution is 0.5 wt % or less. The pH of the washing solution is preferably more than 0, and the acid concentration in the solution is preferably 12 wt % or less. Preferably, the washing solution contains an organic acid and an inorganic acid.

The complexing agent is preferably a thiourea or a thiourea derivative. The stabilizer is preferably a glycol or a glycol ester.

The present invention also relates to a replenishing solution to be added to the washing solution in continuous or repeated use of the washing solution. The replenishing solution is an aqueous solution containing an acid, a complexing agent, a stabilizer and chloride ions.

The present invention also relates to a method for forming a tin plating layer on a surface of an electrically conductive layer. The method for forming a tin plating layer according to the present invention includes the steps of: bringing a tin ion-containing acidic plating solution and an electrically conductive layer into contact with each other to form an electroless tin plating film on a surface of the electrically conductive layer; washing the plating film by bringing the washing solution and a surface of the plating film on which the plating solution is deposited into contact with each other; and water rinsing the plating film, in this order.

The above-mentioned steps may be continuously carried out by conveyorized processing a substrate including an electrically conductive layer. Preferably, a substrate with a tin plating film formed on an electrically conductive layer is immersed in a washing solution in the washing step.

### Effects of the Invention

When a tin film is formed by electroless plating on an electrically conductive layer, and the tin plating film is then washed by bringing a surface of the tin plating film into contact with a washing solution of the present invention, precipitation of crystals on the plating film surface in subsequent water rinsing can be suppressed. Dissolution of the plating film due to contact with the washing solution, and re-plating of tin hardly occur, and therefore properties of the plating film are maintained, so that a tin plating layer (adhesive layer) having high adhesion with resin etc. can be formed. Further, the washing solution of the present invention is excellent in temporal stability, and hardly causes precipitation or sedimentation of crystals even when continuously used. Accordingly, the frequency of replacement of solutions in a plating bath, a washing bath, a rinsing bath and so on can be reduced, and particularly, efficiency of continuous production by a conveyorized process etc. can be improved.

### MODE FOR CARRYING OUT THE INVENTION

[Washing Solution]

A washing solution of the present invention is a solution for washing a plating film surface after a surface of a copper layer etc. is subjected to an electroless tin plating and before a water rinsing is performed. The washing solution of the present invention is an acidic aqueous solution containing an acid, a complexing agent, a stabilizer and chloride ions. Hereinafter, components contained in the washing solution will be described.

(Acid)

The acid contained in the washing solution of the present invention serves as a pH regulator and a stabilizer for tin ions. The acid may be an organic acid or an inorganic acid. Examples of the inorganic acid include hydrochloric acid, perchloric acid, sulfuric acid, nitric acid, fluoroboric acid and phosphoric acid. Among them, hydrochloric acid or sulfuric acid is preferred from the viewpoint of, for example, solubility of a stannic salt.

The organic acid is preferably one having a pKa of 5 or less. Examples of the organic acid having a pKa of 5 or less include water-soluble organic acids such as saturated fatty acids such as formic acid, acetic acid, propionic acid, butyric acid, valeric acid and caproic acid; unsaturated fatty acids such as acrylic acid, crotonic acid and isocrotonic acid; aliphatic saturated dicarboxylic acids such as oxalic acid, malonic acid, succinic acid, glutaric acid, adipic acid and pimelic acid; aromatic carboxylic acids such as benzoic acid, phthalic acid and cinnamic acid; aliphatic unsaturated dicarboxylic acids such as maleic acid; oxycarboxylic acid acids such as glycolic acid, lactic acid, malic acid and citric acid; carboxylic acids having a substituent, such as β-chloropropionic acid, nicotinic acid, ascorbic acid, hydroxypivalic acid and levulinic acid; and organic sulfonic acids such as sulfamic acid, methanesulfonic acid, ethanesulfonic acid, benzenesulfonic acid, phenolsulfonic acid and cresolsulfonic acid. Among them, oxycarboxylic acids or organic sulfonic acids are preferred for improving temporal stability of the washing solution.

The acids may be used singly, or used in combination of two or more thereof. When two or more acids are used, two or more inorganic acids may be used, or two or more organic acids may be used. Organic acids and inorganic acids may be used in combination. Inorganic acids are preferably used for increasing solubility of a tin salt to improve washing property of a tin plating film surface. On the other hand, organic acids are preferably used for improving temporal stability (continuous usability) of the washing solution. Preferably, organic acids and inorganic acids are used in combination for attaining both washing property and temporal stability of the washing solution, and suppressing dissolution (etching) of a tin plating film.

For improving washing property of a tin plating film surface while suppressing degeneration of a tin plating film by dissolution etc., the pH of the washing solution is preferably more than 0 and less than 7, more preferably 0.1 to 5, further preferably 0.5 to 3. For improving washing property of a tin plating film surface while properly keeping the pH of the washing solution to suppress degeneration of a tin plating film by dissolution etc., the concentration of the inorganic acid in the washing solution is preferably 0.05 to 5 wt %, more preferably 0.1 to 3 wt %, further preferably 0.15 to 2 wt %. For suppressing precipitation of a tin salt in the washing solution to improve temporal stability of the washing solution while suppressing fluctuation of pH of the washing solution, the concentration of the organic acid in the washing solution is preferably 0.3 to 11 wt %, more preferably 0.5 to 9 wt %, further preferably 0.8 to 8 wt %. The acid concentration (total of inorganic acid concentration and organic acid concentration) in the washing solution is preferably 0.4 to 12 wt %, more preferably 0.8 to 10 wt %, further preferably 1 to 9 wt %, especially preferably 1.2 to 8 wt %.

(Complexing Agent)

The complexing agent contained in the washing solution of the present invention has an effect of suppressing a change in surface property due to, for example, dissolution of a plating film in an acid by coordinating to a plating film surface or an underlying electrically conductive layer (e.g., copper layer or copper alloy layer) to form a chelate. Examples of the complexing agent that is preferably used include thioureas such as thiourea, 1,3-dimethylthiourea, 1,3-diethyl-2-thiourea, trimethylthiourea and acetylthiourea; and thiourea derivatives such as thiourea dioxide and thiosemicarbazide. In addition, ethylenediaminetetraacetic acid (EDTA), disodium ethylenediaminetetraacetate (EDTA.2Na), hydroxyethylenediaminetriacetic acid (HEDTA), diethylenetriaminepentaacetic acid (DTPA), triethylenetetraminehexaacetic acid (TTHA), ethylene diaminetetrapropionic acid, ethylenediaminetetramethylenephosphoric acid, diethylenetriaminepentamethylenephosphoric acid, nitrilotriacetic acid (NTA), iminodiacetic acid (IDA), iminodipropionic acid (IDP), aminotrimethylenephosphoric acid, pentasodium aminotrimethylenephosphate, benzylamine, 2-naphthylamine, isobutylamine, isoamylamine, methylenediamine, ethylenediamine, tetramethylenediamine, pentamethylenediamine, hexamethylenediamine, diethylenetriamine, tetraethylenepentamine, pentaethylenehexamine, hexaethyleneheptamine, cinnamylamine, p-methoxycinnamylamine and the like can be used as the complexing agent.

The concentration of the complexing agent in the washing solution is preferably 0.5 to 20 wt %, more preferably 1 to 15 wt %, further preferably 1.5 to 10 wt %. When the concentration of the complexing agent is within a range as described above, a surface can be washed while a change in surface property of a tin plating film is suppressed, and therefore precipitation of crystals on the plating film surface can be suppressed.

(Stabilizer)

The stabilizer contained in the washing solution of the present invention has an effect of maintaining the concentration of each of components necessary for washing in the vicinity of a plating film surface, and increasing solubility of a tin salt in the washing solution. Examples of the stabilizer may be glycols such as ethylene glycol, diethylene glycol, propylene glycol and tripropylene glycol, and glycol esters such as cellosolve, carbitol and butyl carbitol.

The concentration of the stabilizer in the washing solution is preferably 2 to 75 wt %, more preferably 3 to 60 wt %, further preferably 4 to 50 wt %. When the concentration of the complexing agent is within a range as described above, the concentration of each of components necessary for washing can be maintained in the vicinity of a plating film surface, and solubility of a tin salt in the washing solution can be increased. Thus, by the effect of dissolving tin ions and a tin salt on the film surface in the washing solution, the washing ability can be increased, and precipitation of a tin salt etc. in the washing solution can be suppressed.

(Chloride Ion)

The washing solution of the present invention has a chloride ion concentration of 2 wt % or more. The chloride ion concentration is preferably 3 wt % or more, more preferably 4 wt % or more. The chloride ion has an effect of helping dissolution of a tin salt in the washing solution to improve temporal stability (continuous usability) when the washing solution is continuously used. Although the upper limit of the chloride ion concentration is not particularly limited, it is preferably 20 wt % or less, more preferably 15 wt % or less from the viewpoint of solubility. By blending a chloride ion source, chloride ions can be contained in the washing solution.

Examples of the chloride ion source include hydrochloric acid, sodium chloride, calcium chloride, potassium chloride, ammonium chloride, copper chloride, zinc chloride and iron chloride. In addition to these compounds, compounds capable of dissociating halide ions in an aqueous solution can be used as the chloride ion source. The chloride ion sources may be used in combination of two or more thereof.

For improving washing efficiency of the washing solution, and suppressing a change in surface property due to, for example, precipitation of different kinds of metals on the surface, alkali metal salts such as sodium chloride and calcium chloride, alkali earth metal salts such as calcium chloride, ammonium chloride, hydrochloric acid and so on are preferably used as the chloride ion source. Hydrochloric acid can be used as one having both the effect as a chloride ion source and the effect as an acid. In this regard, when the concentration of hydrochloric acid is excessively high, the pH of the washing solution may decrease, leading to occurrence of a change in surface property due to dissolution of a tin plating film, re-plating or the like. Thus, when hydrochloric acid is used, it is preferred to set the chloride ion concentration within the above-mentioned range by using other chloride ion source in combination.

(Other Additives)

In addition to the components described above, a reducing agent, a brightener, a pH adjuster, a surfactant, a preservative and so on can be appropriately added to the washing solution of the present invention. The content of these additive components is, for example, about 0.1 to 20 wt %.

The washing solution of the present invention can be prepared by dissolving the above-mentioned components in water. The water is preferably water freed of ionic substances and impurities, and for example, ion-exchanged water, pure water, ultrapure water or the like is used.

(Tin Concentration of Washing Solution)

The washing solution of the present invention has a tin concentration of 0.5 wt % or less. The tin concentration is a concentration of the tin element including tin ions (Sn²⁺ and Sn⁴⁺). By decreasing the tin concentration in the solution, efficiency of removal of tin ions deposited on a plating film surface is improved. Thus, re-plating in the washing process can be suppressed, and precipitation of a tin salt on a film surface can be suppressed. The tin concentration in the washing solution is preferably 0.4 wt % or less, more preferably 0.35 wt % or less. The tin concentration in the solution can be measured using a Zeeman atomic absorption spectrophotometer.

Preferably, the washing solution of the present invention is substantially free of tin, and has a tin concentration of 0.05 wt % or less before use (fresh solution). With use of the washing solution, a plating solution deposited on a plating film surface is carried in the washing solution, so that the tin concentration in the solution tends to increase. When the washing solution is continuously or repeatedly used, it is preferred to replace the washing solution when the tin concentration exceeds a predetermined value for keeping washing performance uniform.

[Replenishing Solution]

The replenishing solution of the present invention is to be added to the washing solution in continuous or repeated use of the washing solution, and the replenishing solution is an acidic aqueous solution containing an acid, a complexing agent, a stabilizer and chloride ions. By adding the replenishing solution to the washing solution, the ratio of the components in the washing solution can be properly kept to stably maintain a washing effect.

The concentration of each of the components in the replenishing solution is appropriately set according to the concentration of each of the components in the washing solution, the composition of the plating solution, and so on. The preferred range of the concentration of each of the acid, the complexing agent, the stabilizer and the chloride ions in the replenishing solution is the same as the foregoing range as a preferred range of the concentration of each of the components in the washing solution. The replenishing solution may contain components other than the above-mentioned acid, complexing agent, stabilizer and chloride ions (chloride ion source).

[Method for Forming Electroless Tin Plating Layer]

The washing solution of the present invention is used for washing a film surface after an electrically conductive layer composed of copper, a copper alloy or the like is subjected to electroless tin plating and before water rinsing is performed. A method for forming a tin plating layer according to the present invention includes the steps of bringing a tin ion-containing acidic plating solution and an electrically conductive layer into contact with each other to form an electroless tin plating film on a surface of the electrically conductive layer (plating step); bringing the washing solution and a surface of the plating film on which the plating solution is deposited into contact with each other (washing step); and water rinsing the plating film (rinsing step), in this order.

The electroless plating is intended to reductively precipitate a metal by an electrochemical oxidation-reduction reaction without using an external power source. In this specification, the electroless plating encompasses both displacement plating using a difference in ionization tendency (potential difference) between different kinds of metals and chemical plating in which a metal is precipitated by an oxidation-reduction reaction in a solution containing a metal and a reducing agent (also referred to as autocatalytic electroless plating or reduction electroless plating).

(Formation of Tin Plating Film)

Preferably, a surface of an electrically conductive layer is washed with an acid etc. as necessary before a tin plating film is formed on the surface of the electrically conductive layer by electroless plating. For example, when the electrically conductive layer is made of copper or a copper alloy, it is preferred to wash the surface of the electrically conductive layer with dilute sulfuric acid.

An electroless tin plating layer is formed by bringing the electrically conductive layer and an electroless tin plating solution into contact with each other. The electroless tin plating solution is a tin ion-containing acidic aqueous solution, and its composition is not particularly limited. A publicly known electroless tin plating solution can be used. The electroless tin plating solution is obtained by blending an acid and a tin salt. The tin salt may be a stannous (Sn²⁺) salt or a stannic (Sn⁴⁺) salt. Further, a stannous salt and a stannic salt can be used in combination. Specific examples of the tin salt include stannous sulfate, stannic sulfate, stannous borofluoride, stannous fluoride, stannic fluoride, stannous nitrate, stannic nitrate, stannous chloride, stannic chloride, stannous formate, stannic formate, stannous acetate and stannic acetate. The tin concentration in the plating solution is preferably 0.5 to 5 wt %. When the pH of the washing solution is made higher than the pH of the plating solution, a change in pH (pH shock) of a plating film surface can be relaxed.

When the electrically conductive layer is made of copper or a copper alloy, it is preferred to form an alloy layer of copper and tin by displacement plating for improving adhesion with resin etc. Preferably, the plating solution for displacement tin plating contains a complexing agent and a stabilizer in addition to an acid and a tin salt. The complexing agent contained in the displacement tin plating solution has an effect of promoting formation of a tin plating film on a surface of an electrically conductive layer by coordinating to the electrically conductive layer to form a chelate. The stabilizer has an effect of maintaining the concentration of each of components necessary for reaction in the vicinity of the surface of the electrically conductive layer. As the complexing agent and the stabilizer, the complexing agent and stabilizer described above as components in the washing solution are preferably used. The complexing agent and the stabilizer in the plating solution may be identical to or different from the complexing agent and the stabilizer in the washing solution.

The displacement tin plating solution may contain a salt of a third metal other than copper and tin (e.g., silver, zinc, aluminum, titanium, bismuth, chromium, iron, cobalt, nickel, palladium, gold, platinum or the like) in addition to a tin salt (see, for example, Japanese Patent Laid-open Publication No. 2004-349698). The displacement tin plating solution may contain a complex formation suppressing agent such as a phosphoric acid, a phosphorous acid, a hypophosphoric acid or the like for the purpose of suppressing a complex forming reaction of the complexing agent with copper (see, for example, Japanese Patent Laid-open Publication No. 2010-13516).

A tin plating film is formed on a surface of an electrically conductive layer by bringing the surface of the electrically conductive layer into a plating solution. The plating conditions are not particularly limited. For example, in the case of displacement tin plating, the surface of the electrically conductive layer may be immersed for about 5 seconds to 5 minutes in a plating solution at a temperature of about 20 to 70° C. (preferably 20 to 40° C.).

(Washing)

An electrically conductive layer provided with a tin plating film by electroless plating is in a state in which a plating solution is deposited on a surface of the plating film when the electrically conductive layer is removed from the plating solution. In this state, washing (acid washing) using the washing solution of the present invention is performed before water rinsing. The washing is performed by bringing the washing solution and the surface of the tin plating film into contact with each other. As a method for bringing the tin plating film and the washing solution into contact with each other, for example, a surface of the tin plating film is immersed in the washing solution, or the washing solution is sprayed to the tin plating film. For improving washing efficiency, it is preferred that a surface of the tin plating film is immersed in the washing solution. When the plating film is immersed in the washing solution, the temperature of the washing solution is preferably 10 to 70° C., more preferably 20 to 40° C. The immersion time is preferably 2 to 120 seconds, more preferably 5 to 60 seconds.

Washing may be performed in two or more stages. For example, when washing with the washing solution of the present invention is performed in two stages in a conveyorized process, a first washing bath and a second washing bath are provided between a plating bath and a rinsing bath. When washing is performed in two or more stages as described above, the compositions of the washing solutions in the washing baths may be identical to or different from one another.

Since a plating solution deposited on a surface of the plating film is carried in the washing solution, the composition is fluctuated with use of the washing solution. For suppressing deterioration of washing property due to fluctuation of the composition, it is preferred to perform washing while adding the replenishing solution to the washing solution. By adding the replenishing solution, the concentration of each of the acid, the complexing agent, the stabilizer and the chloride ions can be kept constant, but the tin content in the washing solution tends to increase with use of the washing solution. When a throughput with the washing solution (washing area of the substrate) increases, so that the tin concentration in the washing solution increases, washing performance may be deteriorated, or precipitation or sedimentation of crystals in the washing solution may occur. It is preferred to replace the washing solution when the tin ion concentration in the washing solution exceeds a predetermined value as described above.

(Rinsing)

A plating film after washing with the washing solution of the present invention and water is brought into contact with other to perform water rinsing. The rinsing conditions are not particularly limited. Water rinsing may be performed in two or more stages. In the present invention, washing is performed after electroless plating and before water rinsing, and therefore precipitation of a tin salt etc. on a plating film surface in water rinsing can be suppressed.

The steps of plating, washing and rinsing may be carried out in a batch, or carried out continuously by conveyorized process of a substrate including an electrically conductive layer. For improving plating efficiency, a conveyorized process is preferred. Even when repeatedly or continuously used, the washing solution of the present invention has high solution stability, so that precipitation or sedimentation of crystals in the solution hardly occurs, and therefore a plating film surface is hardly contaminated even when conveyorized process is performed.

(Treatment after Rinsing)

A film (tin plating layer) on the electrically conductive layer is dried as necessary, then bonded to resin or solder, and put into practical use. Other layer may be laminated on a surface of the tin plating layer before the tin plating layer is bonded to resin, solder or the like. For the purpose of, for example, improving surface smoothness of the tin plating layer, a tin releasing liquid (aqueous solution of nitric acid, hydrochloric acid, sulfuric acid or the like capable of etching tin) may be brought into contact with the surface of the tin plating layer to etch the tin plating layer in a certain amount in the depth direction (see, for example, Japanese Patent Laid-open Publication No. 2010-13516).

(Lamination of Resin Layer)

In formation of a multilayer wiring board, a resin layer is laminated on the electrically conductive layer. When a tin plating layer is formed in the present invention, a resin layer is laminated on the tin plating layer. As a method for laminating a resin layer, a method such as lamination pressing, lamination or coating can be employed. Examples of the resin component in the resin layer include thermoplastic resins such as acrylonitrile/styrene copolymer resin (AS resin), acrylonitrile/butadiene/styrene copolymer resin (ABS resin), fluororesin, polyamide, polyethylene, polyethylene terephthalate, polyvinylidene chloride, polyvinyl chloride, polycarbonate, polystyrene, polysulfone, polypropylene and liquid crystal polymers; and thermosetting resins such as epoxy resin, phenol resin, polyimide, polyurethane, bismaleide/triazine resin, modified polyphenylene ether and cyanate esters. These resins may be modified with functional groups, or reinforced with glass fibers, aramid fibers, other fibers or the like.

### EXAMPLES

Examples of the present invention are described below along with comparative examples. The present invention is not limited to the following examples.

### Reference Example

A substrate with a 17 μm-thick electrolytic copper plating layer formed on an epoxy resin-impregnated glass fabric copper-clad laminate (R-1766, manufactured by Panasonic Electric Works Co., Ltd., copper foil thickness: 18 μm) was cut into a size of 100 mm×100 mm. This was immersed in 10 wt % sulfuric acid for 30 seconds to wash a surface of the copper plating layer, and water rinsed and dried to obtain a test substrate. The test substrate was subjected to an immersion and oscillation treatment (at 30° C. for 30 seconds) in a displacement tin plating solution (T-9900, manufactured by MEC Co., Ltd.) to form an electroless tin plating film (alloy layer of copper and tin) on a surface of the electrolytic copper plating layer. Thereafter, the test substrate was water rinsed and dried. A surface of the electroless tin plating layer after drying was visually observed, and it was found that white crystals were precipitated on a substrate surface.

### Examples 1 to 19 and Comparative Examples 1 to 7

(Washing with Fresh Solution)

Electroless tin plating was performed in the same manner as in the reference example described above. A copper clad laminate removed from a plating solution was immersed for 10 seconds in a washing solution (25° C.) having a composition as shown in Table 1, and was then water rinsed and dried in the same manner as in the reference example. In Comparative Example 7, a tin salt (stannous sulfate) was blended in such a manner that the tin concentration would be 1 wt %. Since the tin salt was partially undissolved, the following evaluations were not performed for Comparative Example 7.

(Washing with Continuously-Used Solution)

A solution (having a composition corresponding to that of a washing solution after a plating solution was carried therein due to continuous use; tin concentration; 0.27 wt %) obtained by adding 30 parts by weight of the displacement tin plating solution to 100 parts by weight of a fresh solution having a composition as shown in Table 1 was used as a washing solution. A copper clad laminate subjected to tin plating in the same manner as in the reference example was immersed for 10 seconds in the washing solution (25° C.), and then water rinsed and dried.

[Evaluation]

(Washing Property)

The surface of the tin plating layer after water rinsing and drying was visually observed. A sample in which white crystals were not precipitated on the surface was rated A, and a sample in which white crystals were precipitated on the surface was rated C.

(Influences on Sn Plating Surface Properties)

The surface of the tin plating layer after water rinsing and drying was visually observed, and the finished state (color and metallic luster) of the surface was compared with that in the reference example (only water rinsing was performed) to determine whether or not the surface was unevenly washed and whether or not etching progressed. The surface was observed with a scanning electron microscope (SEM), and compared with that in the reference example to check a change in surface shape (smoothness). A sample for which the result was the same as that in the reference example for every evaluation item was rated A, and a sample for which the result was different from that in the reference example for at least one of the evaluation items, and thus the substrate surface was influenced by washing was rated C.

(Washing Solution Stability)

The washing solution after use was left standing at room temperature for 3 days, and then visually observed to check stability of the washing solution. A sample in which either turbidity or sedimentation did not occur in the solution was rated A, a sample in which turbidity occurred and sedimentation did not occur in the solution was rated B, and a sample in which both turbidity and sedimentation occurred in the solution was rated C.

The compositions of the washing solutions and evaluation results in examples and comparative examples are shown in Table 1. In preparation of the washing solution, 35 wt % hydrochloric acid and 62.5 wt % sulfuric acid were used as inorganic acids. The concentration of each of the components in the washing solutions shown in Table 1 is a concentration (wt %) as that of a pure substance, and the balance in blended components in each of the washing solutions shown in Table 1 is ion-exchanged water. The pH of the washing solution (fresh solution) of each of examples was measured, and the result showed that the pH was within the range of 0.5 to 3 in each examples. The pH of the washing solution of Comparative Example 3 was a negative value.

TABLE 1

| | Composition of washing solution | | | | | | | Components in | | |
|---|---|---|---|---|---|---|---|---|---|---|
| | Inorganic | | Organic | | | | | washing solution | | |
| | acid | | acid | | | | | Acid | Cl | Sn |
| | | Concen- | | Concen- | | Ethylene | | concen- | concen- | concen- |
| | Type | tration | Type | tration | Thiourea | gylcol | NaCl | tration | tration | tration |
| Reference | Water rinsing-only | | | | | | | — | | |
| Example | | | | | | | | | | |
| Example 1 | HCl | 0.53 | Citric acid | 1.20 | 2.4 | 8 | 8 | 1.73 | 5.37 | 0 |
| Comparative | HCl | 0.53 | Citric acid | 1.20 | 2.4 | 8 | 0 | 1.73 | 0.51 | 0 |
| Example 1 | | | | | | | | | | |
| Comparative | HCl | 0.53 | Citric acid | 1.20 | 2.4 | 8 | 2 | 1.73 | 1.72 | 0 |
| Example 2 | | | | | | | | | | |
| Example 2 | HCl | 0.53 | Citric acid | 1.20 | 2.4 | 8 | 3 | 1.73 | 2.33 | 0 |
| Example 3 | HCl | 0.53 | Citric acid | 1.20 | 2.4 | 8 | 5 | 1.73 | 3.54 | 0 |
| Example 4 | HCl | 0.53 | Citric acid | 1.20 | 2.4 | 8 | 6.4 | 1.73 | 4.39 | 0 |
| Example 5 | HCl | 0.53 | Citric acid | 1.20 | 2.4 | 8 | 20 | 1.73 | 12.65 | 0 |
| Example 6 | HCl | 0.42 | Citric acid | 1.20 | 2.4 | 8 | 8 | 1.62 | 5.26 | 0 |
| Example 7 | HCl | 0.63 | Citric acid | 1.20 | 2.4 | 8 | 8 | 1.83 | 5.47 | 0 |
| Example 8 | H₂SO₄ | 0.26 | Citric acid | 1.20 | 2.4 | 8 | 8 | 1.46 | 4.85 | 0 |
| Example 9 | H₂SO₄ | 0.63 | Citric acid | 1.20 | 2.4 | 8 | 8 | 1.83 | 4.85 | 0 |
| Comparative | HCl | 5.25 | Citric acid | 1.20 | 2.4 | 8 | 0 | 6.45 | 5.11 | 0 |
| Example 3 | | | | | | | | | | |
| Example 10 | HCl | 1.05 | — | | 2.4 | 8 | 8 | 1.05 | 5.88 | 0 |
| Example 11 | HCl | 0.53 | Citric acid | 0.80 | 2.4 | 8 | 8 | 1.33 | 5.37 | 0 |
| Example 12 | HCl | 0.53 | Citric acid | 1.44 | 2.4 | 8 | 8 | 1.97 | 5.37 | 0 |
| Example 13 | HCl | 0.53 | Sulfamic acid | 4.80 | 2.4 | 8 | 8 | 5.33 | 5.37 | 0 |
| Example 14 | HCl | 0.53 | Methane- | 4.00 | 2.4 | 8 | 8 | 4.53 | 5.37 | 0 |
| | | | sulfonic acid | | | | | | | |
| Example 15 | HCl | 0.53 | Citric acid | 1.20 | 1.9 | 8 | 8 | 1.73 | 5.37 | 0 |
| Example 16 | HCl | 0.53 | Citric acid | 1.20 | 2.9 | 8 | 8 | 1.73 | 5.37 | 0 |
| Comparative | HCl | 0.53 | Citric acid | 1.20 | 0 | 8 | 8 | 1.73 | 5.37 | 0 |
| Example 4 | | | | | | | | | | |
| Comparative | HCl | 0.53 | Citric acid | 1.20 | 2.4 | 0 | 0 | 1.73 | 0.51 | 0 |
| Example 5 | | | | | | | | | | |
| Comparative | HCl | 0.53 | Citric acid | 1.20 | 2.4 | 0 | 8 | 1.73 | 5.37 | 0 |
| Example 6 | | | | | | | | | | |
| Example 17 | HCl | 0.53 | Citric acid | 1.20 | 2.4 | 2.4 | 8 | 1.73 | 5.37 | 0 |
| Example 18 | HCl | 0.53 | Citric acid | 1.20 | 2.4 | 4 | 8 | 1.73 | 5.37 | 0 |
| Example 19 | HCl | 0.53 | Citric acid | 1.20 | 2.4 | 20 | 8 | 1.73 | 5.37 | 0 |
| Comparative | HCl | 0.53 | Citric acid | 1.20 | 2.4 | 8 | 8 | 1.73 | 5.37 | 1 |
| Example 7 | | | | | | | | | | |
| | | | | | Evaluation results | | | | | |
| | | | | | | | | Continuously-used | | |
| | | | | | Fresh solution | | | solution | | |
| | | | | | | | washing | | | washing |
| | | | | | Washing | Sn | solution | Washing | Sn | solution |
| | | | | | property | film | stability | property | film | stability |
| | | | | Reference | C | A | — | — | | |
| | | | | Example | | | | | | |
| | | | | Example 1 | A | A | A | A | A | A |
| | | | | Comparative | A | A | A | A | A | C |
| | | | | Example 1 | | | | | | |
| | | | | Comparative | A | A | A | A | A | C |
| | | | | Example 2 | | | | | | |
| | | | | Example 2 | A | A | A | A | A | B |
| | | | | Example 3 | A | A | A | A | A | B |
| | | | | Example 4 | A | A | A | A | A | A |
| | | | | Example 5 | A | A | A | A | A | A |
| | | | | Example 6 | A | A | A | A | A | A |
| | | | | Example 7 | A | A | A | A | A | A |
| | | | | Example 8 | A | A | A | A | A | A |
| | | | | Example 9 | A | A | A | A | A | A |
| | | | | Comparative | A | C | A | A | C | A |
| | | | | Example 3 | | | | | | |
| | | | | Example 10 | A | A | A | A | A | B |
| | | | | Example 11 | A | A | A | A | A | A |
| | | | | Example 12 | A | A | A | A | A | A |
| | | | | Example 13 | A | A | A | A | A | A |
| | | | | Example 14 | A | A | A | A | A | A |
| | | | | Example 15 | A | A | A | A | A | A |
| | | | | Example 16 | A | A | A | A | A | A |
| | | | | Comparative | A | C | A | A | C | C |
| | | | | Example 4 | | | | | | |
| | | | | Comparative | A | A | A | A | A | C |
| | | | | Example 5 | | | | | | |
| | | | | Comparative | A | A | A | A | A | C |
| | | | | Example 6 | | | | | | |
| | | | | Example 17 | A | A | A | A | A | B |
| | | | | Example 18 | A | A | A | A | A | A |
| | | | | Example 19 | A | A | A | A | A | A |
| | | | | Comparative | — | | | | | |
| | | | | Example 7 | | | | | | |

The evaluation results for “washing property” in Table 1 show that in all examples and comparative examples (excluding Comparative Example 7), precipitation of crystals on the surface of the electroless tin plating film is suppressed by performing washing with an acidic washing solution after electroless tin plating and before water rinsing. Comparison between Examples 1 to 5 and Comparative Examples 1 and 2 shows that as the chloride ion concentration in the washing solution increases, continuous-use stability of the washing solution is improved, and even when washing is performed with a continuously-used solution (containing 0.27 wt % of tin), precipitation or sedimentation of crystals in the solution is suppressed.

In Comparative Example 3 where the washing solution contained only hydrochloric acid as a chloride ion source, the washing solution had high continuous-use stability as in the case of examples, but the acid concentration was high (the pH was low), and therefore a surface change occurred due to dissolution of the tin plating film. These results suggest that when hydrochloric acid is used as the acid, it is preferred that for attaining both stability of the washing solution and suppression of damage to the plating film, a chloride ion source other than hydrochloric acid is used in combination to adjust the chloride ion concentration.

The results of Examples 8 and 9 where sulfuric acid was used as an inorganic acid show that even when an inorganic acid other than hydrochloric acid is used, both stability of the washing solution and suppression of damage to the plating film can be attained by adjusting the chloride ion concentration. The results of Examples 13 and 14 show that even when an organic acid other than citric acid is used, washing property and solution stability comparable to washing property and solution stability in other examples are obtained. In Example 10 where an organic acid was not used, and only an inorganic acid was used, the washing solution had an equivalent chloride ion concentration, but was slightly poorer in continuous-use stability as compared to other examples where an organic acid and an inorganic acid were used in combination. This result shows that by using an organic acid and an inorganic acid as the acid, stability of the washing solution is improved as compared to a case where a single acid is used.

When the washing solution of Comparative Example 4 which did not contain a complexing agent (thiourea) was used, a change in properties of the plating film occurred. When the washing solution of Comparative Example 5 or 6 which did not contain a stabilizer (diethylene glycol) was used, continuous-use stability of the plating solution was deteriorated. Comparison between Comparative Example 6 and Examples 17 to 19 shows that continuous-use stability of the washing solution is improved as the stabilizer concentration increased.

The above results show that by washing the plating film using the washing solution of the present invention after electroless tin plating and before water rising, precipitation of crystals in water rinsing can be suppressed while the properties of the tin plating film are maintained. Even when tin ions in the plating solution are carried in the washing solution due to repeated used or continuous use, so that the tin concentration in the washing solution increases, precipitation or sedimentation of crystals hardly occurs in the washing solution of the present invention, and thus the washing solution of the present invention is excellent in continuous usability (temporal stability).

1. A washing solution for washing an electroless tin plating film with a tin ion-containing acidic plating solution deposited on a surface thereof, wherein
the washing solution is an aqueous solution containing an acid, a complexing agent, a stabilizer and a chloride ion,
pH of the washing solution is more than 0 and less than 7,
a chloride ion concentration is 2 wt % or more, and a tin concentration is 0.5 wt % or less.

2. The washing solution according to claim 1, wherein the acid contains an organic acid and an inorganic acid.

3. The washing solution according to claim 1, wherein an acid concentration is 12 wt % or less.

4. The washing solution according to claim 1, wherein the complexing agent is at least one selected from the group consisting of thioureas and thiourea derivatives.

5. The washing solution according to claim 1, wherein the stabilizer is at least one selected from the group consisting of glycols and glycol esters.

6. A replenishing solution to be added to a washing solution in continuous or repeated use of the washing solution for washing an electroless tin plating film with a tin ion-containing acidic plating solution deposited on a surface thereof wherein
the replenishing solution is an aqueous solution containing an acid, a complexing agent, a stabilizer and a chloride ion.

7. A method for forming a tin plating layer on a surface of an electrically conductive layer, comprising in the following order:
plating step of bringing a tin ion-containing acidic plating solution and an electrically conductive layer into contact with each other to form an electroless tin plating film on a surface of the electrically conductive layer;
washing step of bringing the washing solution according to claim 1 and a surface of the plating film into contact with each other; and
rinsing step of water rinsing the plating film.

8. The method for forming a tin plating layer according to claim 7, wherein, in the washing step, a tin plating film surface is immersed in the washing solution to bring the washing solution into contact with the tin plating film surface.

9. The method for forming a tin plating layer according to claim 7, wherein the plating film surface is washed while a replenishing solution is added to the washing solution in the washing step, wherein the replenishing solution is an aqueous solution containing an acid, a complexing agent, a stabilizer and a chloride ion.

10. The method for forming a tin plating layer according to claim 7, wherein a substrate including an electrically conductive layer is subjected to a conveyorized process for continuously carrying out the plating step, the washing step and the rinsing step.
